(19) United States
(12) Patent Application Publication
(10) Pub. No.: US 2026/0247921 A1
(43) Pub. Date: Aug. 20, 2026

(54) ADHESIVE FILM FOR SEMICONDUCTOR

(71) Applicant: YOULCHON CHEMICAL CO., LTD., Seoul (KR)

(72) Inventors: Ji Moon LEE, Ansan-si (KR); Sang Gil DOH, Ansan-si (KR); Gyeong Seok YU, Ansan-si (KR); Kyu Wan LEE, Ansan-si (KR); Chang Woo LEE, Ansan-si (KR); Young Hun JANG, Ansan-si (KR); Han Bin CHO, Ansan-si (KR); Tae Yong HA, Ansan-si (KR); Kyoung Mi SONG, Ansan-si (KR)

(73) Assignee: YOULCHON CHEMICAL CO., LTD., Seoul (KR)

(21) Appl. No.: 19/162,132

(22) PCT Filed: Nov. 20, 2024
(86) PCT No.: PCT/KR2024/018370

§ 371 Date: Sep. 4, 2025

(30) Foreign Application Priority Data
Dec. 11, 2023 (KR) 10-2023-0178854
Jul. 31, 2024 (KR) 10-2024-0101920
Oct. 29, 2024 (KR) 10-2024-0149842

(51) Int. Cl. H10P 72/70; C09J 7/29

(52) U.S. Cl. CPC H10P 72/7406; C09J 7/29

(57) ABSTRACT

According to an embodiment of the present disclosure, a semiconductor adhesive film includes a base layer, a conductive layer formed on the base layer, and an adhesive layer formed on the conductive layer, in which the semiconductor adhesive film has a surface resistance in the range of 1×10¹¹ to 1×10¹³ Ω/sq when a voltage of 1 kV is applied, and a thickness of the adhesive layer of 15 to 50 μm. According to the present disclosure, the semiconductor adhesive film can stably fix a semiconductor wafer to an electrostatic chuck and simultaneously protect the wafer when adhering to a semiconductor.

### TECHNICAL FIELD

The present disclosure relates to a semiconductor adhesive film, and more particularly, to a semiconductor adhesive film which has electrical properties in a predetermined range when adhering to a semiconductor wafer, and can minimize the occurrence of burr or bubbles that may occur when adhering to the semiconductor wafer.

### BACKGROUND ART

Recently, there has been an increasing demand for thinning and miniaturization of semiconductor devices and their packages. Accordingly, as semiconductor wafers become thinner, electrostatic chucks (ESCs) are used to effectively fix the semiconductor wafers. The ESC is a device used to fix the wafer in a semiconductor manufacturing process, and fixes the wafer using electrical force, and minimizes damage due to contact and provides uniform fixing force, unlike conventional physical clamps or vacuum suction methods.

In order to fix the semiconductor wafer to the ESC, a semiconductor adhesive film may adhere to the wafer. At this time, in order to fix the wafer to the ESC through an electrical force, the semiconductor adhesive film needs to have suitable electrical properties, and simultaneously to minimize the occurrence of burr or bubbles that may occur when adhering to the semiconductor wafer.

### PRIOR ARTS

### Patent Documents

(Patent Document 1) KR 10-2208071 B1

### DISCLOSURE

### Technical Problem

In order to solve the above problems, an object of the present disclosure is to provide a semiconductor adhesive film including an adhesive layer formed on a conductive layer and having electrical properties in a predetermined range.

Another object of the present disclosure is to provide a semiconductor adhesive film capable of minimizing the occurrence of burr or voids that may occur when adhering to a semiconductor wafer.

### Technical Solution

According to an embodiment of the present disclosure, a semiconductor adhesive film includes a base layer, a conductive layer formed on the base layer, and an adhesive layer formed on the conductive layer, in which the semiconductor adhesive film has surface resistance in the range of 1×10¹¹ to 1×10¹³ Ω/sq when a voltage of 1 kV is applied, and a thickness of the adhesive layer of 15 to 50 μm.

In the semiconductor adhesive film according to an embodiment of the present disclosure, the thickness of the adhesive layer may be formed to be 50% or less of the thickness of the semiconductor adhesive film.

In the semiconductor adhesive film according to an embodiment of the present disclosure, the conductive layer may have a thickness of 0.03 to 3 μm.

The semiconductor adhesive film according to an embodiment of the present disclosure may further include a release film formed on the adhesive layer.

In the semiconductor adhesive film according to an embodiment of the present disclosure, the adhesive layer may be bonded to the entire semiconductor wafer within 1.0 s from a time point at which the center of the semiconductor adhesive film is pressed to bring the semiconductor wafer into contact with the adhesive layer.

In the semiconductor adhesive film according to an embodiment of the present disclosure, the adhesive layer may include at least one selected from the group consisting of a rubber-based compound, an acrylic-based compound, a silicone-based compound, and a urethane-based compound.

In the semiconductor adhesive film according to an embodiment of the present disclosure, the thickness of the adhesive layer may be 15 to 35 μm or 15 to 25 μm.

In the semiconductor adhesive film according to an embodiment of the present disclosure, the thickness of the base layer is 25 to 100 μm, 33 to 70 μm, or 38 to 50 μm.

### Advantageous Effects

According to the present disclosure, the semiconductor adhesive film can stably fix semiconductor wafers to electrostatic chucks and simultaneously protect the wafers when adhering to a semiconductor.

The semiconductor adhesive film according to the present disclosure can minimize burr and bubbles that may occur when adhering to the semiconductor.

### DESCRIPTION OF DRAWINGS

FIG. 1 is a cross-sectional view of a semiconductor adhesive film according to an embodiment of the present disclosure;

FIG. 2 is a cross-sectional view of a semiconductor adhesive film according to another embodiment of the present disclosure;

FIG. 3 is a state diagram in which a semiconductor adhesive film according to an embodiment of the present disclosure adheres to a semiconductor wafer;

FIG. 4 is a state diagram in which the semiconductor adhesive film according to an embodiment of the present disclosure is bonded to the entire semiconductor wafer;

FIG. 5 is a state diagram in which the semiconductor adhesive film according to an embodiment of the present disclosure is not bonded to the semiconductor wafer;

FIG. 6 is a photograph of an apparatus for performing a burr test on the semiconductor adhesive film according to an embodiment of the present disclosure; and

FIGS. 7 to 12 are photographs of films after a burr test on the semiconductor adhesive film according to an embodiment of the present disclosure.

### BEST MODE

Hereinafter, various embodiments of the present disclosure will be described in detail with reference to the accompanying drawings. The present disclosure is not limited to specific embodiments, and it should be understood to include various modifications, equivalents, and/or alternatives to the embodiments of the present disclosure. In connection with the description of the drawings, similar reference numerals may be used for similar components.

In present disclosure, expressions such as “have”, “may have”, “include”, or “may include” refer to the presence of the corresponding feature (e.g., components such as numerical values, functions, operations, or components), and do not exclude the presence of additional features.

In the present disclosure, the expression such as “A or B”, “at least one of A or/and B”, or “one or more of A or/and B” may include all possible combinations of items listed together. For example, “A or B”, “at least one of A and B”, or “at least one of A or B” may refer to all cases of (1) including at least one A, (2) including at least one B, or (3) including both at least one A and at least one B.

The expression of “configured to (or set to)” used herein may be changed and used to, for example, “suitable for”, “having the capacity to”, “designed to”, “adapted to”, “made to” or “capable of”, depending on a situation. The term of “configured to (or set to)” does not necessarily mean only “specially designed to”.

The terms used herein are used to illustrate only specific embodiments, and may not be intended to limit the scope of other embodiments. A singular expression may include a plural expression unless the context clearly indicates otherwise. The terms used herein, including technical or scientific terms, may have the same meaning as generally understood by those of ordinary skill in the art described in the present disclosure. The terms defined in a general dictionary among the terms used herein may be interpreted in the same or similar meaning as or to the meaning on the context of the related art, and will not be interpreted as an ideal or excessively formal meaning unless otherwise defined in the present disclosure. In some cases, even the terms defined in the present disclosure can not be interpreted to exclude the embodiments of the present disclosure.

Therefore, the configurations of the embodiments described in the present specification are merely the most preferred embodiment of the present disclosure and are not intended to represent all of the technical ideas of the present disclosure, and thus, it should be understood that there are various equivalents and modifications capable of replacing the configurations at the time of this application.

Throughout the specification, when a certain part “includes” a certain component, unless otherwise specifically stated, it is meant to further include other components rather than excluding other components.

The objects, specific advantages, and new features of the present disclosure will be more clearly understood from the following detailed description and the preferred embodiments taken in conjunction with the accompanying drawings. In the present specification, when reference numerals refer to components of each drawing, it is to be noted that although the same components are illustrated in different drawings, the same components are denoted by the same reference numerals as possible. Further, the terms “one surface”, “other surface”, “first”, “second”, etc. are used to distinguish one component from the other component and the components are not limited by the terms. Hereinafter, in describing the present disclosure, a detailed description of related known art which may make the gist of the present disclosure unnecessarily obscure will be omitted.

Hereinafter, an embodiment of the present disclosure will be described in detail with reference to the accompanying drawings, and the same reference numerals denote the same members.

As used herein, an “electrostatic chuck” as ESC refers to a device that is used to fix a wafer or a film (process tape) in a semiconductor manufacturing process. This device may prevent various problems that may occur during the process by fixing the wafer using static electricity instead of a physical method. The electrostatic chuck has a principle of fixing the wafer using an electrostatic force. This method is a method of generating an electrostatic chuck force by applying a voltage between the wafer and the electrostatic chuck. The electrostatic chuck is generally designed to have a monopolar or bipolar structure, and each structure may be classified according to the number of electrodes.

As used herein, the “reaction with the electrostatic chuck” refers to that when the semiconductor adhesive film to be described below is positioned close to the electrostatic chuck and a voltage is applied to the electrostatic chuck, mutual static electricity is generated between the semiconductor adhesive film and the electrostatic chuck, so that the electrostatic chuck and the semiconductor adhesive film may be electrostatically chucked by electrostatic attraction.

According to an embodiment of the present disclosure, a semiconductor adhesive film 1 includes a base layer 10, a conductive layer 20 formed on the base layer 10, and an adhesive layer 30 formed on the conductive layer 20, and has surface resistance in the range of 1×10¹¹ to 1×10¹³ Ω/sq when a voltage of 1 kV is applied, and a thickness of the adhesive layer 30 of 15 to 50μ m.

The semiconductor adhesive film 1 according to another embodiment of the present disclosure may further include a release film 40 formed on the adhesive layer 30.

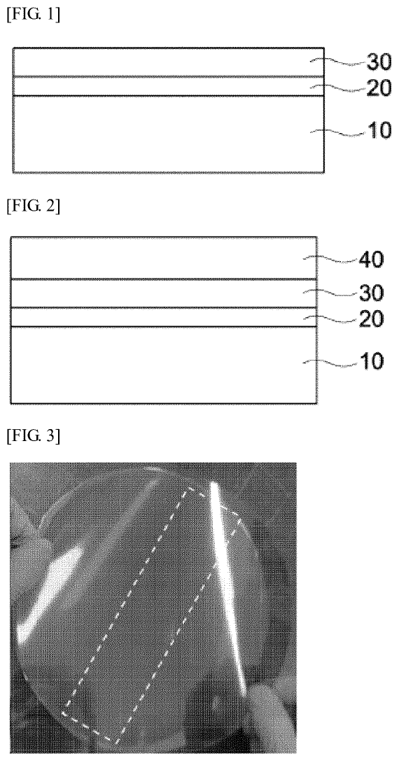

Referring to FIG. 1, the semiconductor adhesive film 1 according to an embodiment of the present disclosure is formed so that the base layer 10, the conductive layer 20, and the adhesive layer 30 are laminated in sequence.

The base layer 10 may be selected from the group consisting of polyethylene terephthalate, polyethylene, polyimide, acrylic resin, cycloolefin polymer, mixtures thereof, and copolymers thereof.

In addition, the semiconductor adhesive film 1 of the present disclosure may further include a release film 40 formed on the adhesive layer 30 as illustrated in FIG. 2.

When the voltage of 1 kV is applied to the semiconductor adhesive film 1 according to an embodiment of the present disclosure, the surface resistance may be 1×10¹¹ to 1×10¹³ Ω/sq. When the surface resistance is less than the above range, the dielectric loss is increased, and thus a wafer W to which the semiconductor adhesive film 1 adheres may not be fixed to the electrostatic chuck. On the contrary, when the surface resistance exceeds the above range, the dielectric loss is reduced, but the fluidity of electrons is reduced, and thus the wafer W to which the semiconductor adhesive film 1 adheres is not fixed to the electrostatic chuck.

The present disclosure has a main feature that electrical properties such as surface resistance, dielectric loss or dielectric constant of each layer and the semiconductor adhesive film 1 formed by combining the layers are precisely controlled, so that the film may be stably fixed to the electrostatic chuck.

In the semiconductor adhesive film 1 according to an embodiment of the present disclosure, the thickness of the adhesive layer 30 may be 15 to 35 μm or 15 to 25 μm.

In addition, the thickness of the adhesive layer 30 may be 15 to 50 μm, 15 to 35 μm, or 15 to 25 μm. When the thickness of the adhesive layer 30 is less than the above range, the dielectric loss is increased, and thus the wafer W to which the semiconductor adhesive film 1 adheres may not be fixed to the electrostatic chuck. On the contrary, when the thickness exceeds the above range, the dielectric loss is decreased, and thus the wafer W to which the semiconductor adhesive film 1 adheres may not be fixed to the electrostatic chuck. In addition, when the thickness of the adhesive layer 30 exceeds the above ranges, a probability that burr is generated when the film 1 is cut is increased.

In the semiconductor adhesive film 1 according to an embodiment of the present disclosure, the thickness of the adhesive layer may be formed to be 50% or less of the thickness of the semiconductor adhesive film.

In addition, the thickness of the adhesive layer 30 may be 50% or less of the thickness of the semiconductor adhesive film 1. When the thickness of the adhesive layer 30 exceeds the above range, the flexibility of the adhesive layer 30 increases the overall flexibility of the film 1 to weaken the stiffness of the film 1, thereby increasing the probability of voids occurring when the film 1 adheres to the wafer W.

In the semiconductor adhesive film 1 according to an embodiment of the present disclosure, the conductive layer 20 may have a thickness of 0.03 to 3 μm.

The conductive layer 20 may be selected from the group consisting of poly(3,4-ethylenedioxythiophene (PEDOT), poly(3,4-ethylenedioxythiophene) polystyrenesulfonate (PEDOT-PSS), carbon nanotubes (CNT), graphene, indium tin oxide (ITO), silver nanowires, and combinations thereof. The conductive layer 20 constituting the present disclosure is characterized to essentially require transparency in addition to the electrical properties.

In addition, the conductive layer 20 may be formed by crosslinking a mixture of poly(3,4-ethylenedioxythiophene) polystyrenesulfonate and water-dispersed polyurethane with aziridine. When the adhesive layer 30 is formed on the conductive layer 20, the conductive layer 20 may partially be removed by a solvent that dissolves materials constituting the adhesive layer 30. In order to prevent the problem, it is necessary to improve the solvent resistance of the conductive layer 20, but in the present disclosure, the solvent resistance is achieved by crosslinking with aziridine.

In addition, a weight ratio of polyurethane to poly(3,4-ethylenedioxythiophene) polystyrenesulfonate (PEDOT-PSS) in the conductive layer 20 may be 1:9, 1.5:8.5, or 3:7. When the PEDOT-PSS content is less than the above range, the surface resistance, dielectric loss, and dielectric constant conditions that may react with the electrostatic chuck may not be satisfied. On the other hand, when the content exceeds the above range, physical properties may be satisfied, but the polyurethane is small and thus cannot be sufficiently crosslinked with an aziridine crosslinking agent, so that the solvent resistance is not ensured, and it is also not preferable in an economic aspect.

In addition, the weight ratio of the mixture of poly(3,4-ethylenedioxythiophene) polystyrenesulfonate and water-dispersed polyurethane of the conductive layer 20 to aziridine may be 100:8 to 63, 100:10 to 63, or 100:12 to 63. When the weight ratio of aziridine is less than the above range, the aziridine is not sufficiently crosslinked with a carboxyl group of the water-dispersed polyurethane, so that the solvent resistance is not ensured. On the contrary, when the weight ratio exceeds the above range, unreacted aziridine may migrate to the surface according to time and temperature, which is economically undesirable.

In addition, the mixture of poly(3,4-ethylenedioxythiophene) polystyrenesulfonate and water-dispersed polyurethane of the conductive layer 20 may be a solution dissolved in a solvent selected from the group consisting of water, ethanol, methanol, isopropyl alcohol, and mixtures thereof.

In addition, the solution may further include a stabilizer selected from the group consisting of ethylene glycol, sorbitol and a mixture thereof.

In addition, the concentration of the mixture of poly(3,4-ethylenedioxythiophene) polystyrenesulfonate and polyurethane dissolved in the solvent selected from the group consisting of water, ethanol, methanol, isopropyl alcohol, and mixtures thereof may be 0.8 to 1.2 wt % or 0.8 to 0.9 wt %. When the concentration of the solution is less than the above range, particles of PEDOT-PSS may come out to the surface to generate a coating strip on the coating surface. On the contrary, when the concentration exceeds the above range, the solid content is lowered, and when the Wet thickness is increased, the surface may not be even due to the fluidity of a coating solution on the coating surface.

The thickness of the conductive layer 20 may be 0.03 to 3 μm. When the thickness of the conductive layer 20 is less than the above range, the surface resistance is high and the dielectric loss is decreased, so that the wafer W to which the semiconductor adhesive film 1 adheres may not be fixed to the electrostatic chuck. In addition, when the thickness of the conductive layer 20 exceeds the above range, the surface resistance is low and the dielectric loss is increased, so that the wafer W to which the semiconductor adhesive film 1 adheres may not be fixed to the electrostatic chuck.

In addition, the conductive layer 20 may be gravure-coated on the base layer 10.

In addition, the conductive layer 20 may be dried with hot air at 60 to 100° C. or 20 to 35 Hz for 30 to 90 seconds. When the drying time or the drying temperature is less than the above range, drying is insufficient, and thus curing or volatilization of the solvent is not completely performed, so that electrical properties such as a dielectric constant may be affected.

In the semiconductor adhesive film 1 according to an embodiment of the present disclosure, the adhesive layer 30 may include at least one selected from the group consisting of a rubber-based compound, an acrylic-based compound, a silicone-based compound, and a urethane-based compound.

In the semiconductor adhesive film 1 according to an embodiment of the present disclosure, the adhesive layer 30 may include at least one selected from the group consisting of a rubber-based compound, an acrylic-based compound, a silicone-based compound, and a urethane-based compound, and preferably a silicone-based compound.

The silicone-based compound may be derived from constituent units of organopolysiloxane of the following Chemical Formula 1 or derivative thereof and a hydrogen siloxane copolymer of the following Chemical Formula 2 or derivative thereof.

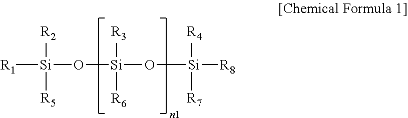

Here, the R₁ and R₈ are each independently any one selected from the group consisting of hydrogen, alkyl and alkenyl, the R₂ to R₇ are either hydrogen or alkyl, and the n1 may be an integer of 5 to 200,000, preferably an integer of 500 to 100,000, and more preferably an integer of 1,000 to 50,000.

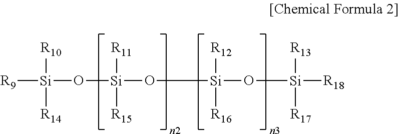

Here, at least one or more of the R₉ to R₁₈ are hydrogen, and the remainder of R₉ to R₁₈ excluding the hydrogen moiety are each independently alkyl, the n2 is an integer of 1 to 200, and the n3 is an integer of 1 to 100.

Preferably, the organopolysiloxane of Chemical Formula 1 or derivative thereof is polydimethylsiloxane containing vinyl groups at both ends, and the molecular weight thereof is 600,000 to 700,000 in weight average molecular weight and 300,000 to 400,000 in number average molecular weight, and the vinyl group content may be 0.02 to 0.2 mmol/g, 0.1 to 0.2 mmol/g, or 0.15 to 0.2 mmol/g. When the vinyl group content is less than the above range, the vinyl group is not sufficiently crosslinked with Si—H and thus may not react with the electrostatic chuck as a dielectric loss value increases. On the contrary, when the vinyl group content exceeds the above range, the crosslinking density with Si—H is increased and thus the vinyl group may not react with the electrostatic chuck as the dielectric loss value decreases.

Preferably, in the hydrogen siloxane copolymer of Chemical Formula 2 or derivative thereof, 1 to 2 hydro groups (—H) may be substituted with an alkyl group having 1 to 2 carbon atoms. More preferably, the hydrogen silxane copolymer of Chemical Formula 2 may be an alkylhydrosiloxane-dialkylsiloxane copolymer, more preferably a methylhydrosiloxane-dimethylsiloxane copolymer, in which the R₁₂ is hydrogen and the remaining R₉ to R₁₁ and R₁₃ to R₁₉ may be substituted with methyl. The weight average molecular weight (Mw) of the hydrogen silaxane copolymer of Chemical Formula 2 may be 1000 to 10,000, and more preferably 1,500 to 4,000.

In addition, the Si—H content of the hydrogen siloxane copolymer of Chemical Formula 2 or derivative thereof may be 4 to 16 mmol/g, 4 to 10 mmol/g, or 4 to 5 mmol/g. When the Si—H content is less than the above range, the hydrogen siloxane copolymer may not be sufficiently crosslinked with the vinyl group included in the organopolysiloxane of Chemical Formula 1 or derivative thereof, and thus the dielectric loss may be increased. On the contrary, when the Si—H content exceeds the above range, unreacted Si—H groups may be generated to migrate to the surface of the adhesive layer.

The silicone-based compound preferably uses platinum as a catalyst in the reaction between the compound of Chemical Formula 1 and the compound of Chemical Formula 2. In addition, in the present disclosure, an addition reaction (curing) step may be particularly applied in order to increase the crosslinking density and decrease the dielectric constant.

A molar ratio of vinyl groups included in the organopolysiloxane of Chemical Formula 1 or derivative thereof to Si—H groups of the hydrogen siloxane copolymer of Chemical Formula 2 or derivative thereof may be 1:1 to 3.

When the molar ratio exceeds the above range, the crosslinking density increases, but an out-gassing phenomenon occurs due to hydrogen gas generated when Si—H that has not reacted with vinyl increases. On the contrary, when the molar ratio is less than the above range, a crosslinking point with vinyl decreases, and thus the crosslinking density and the dielectric constant are decreased, and the dielectric loss is increased, so that it may be difficult to react with the electrostatic chuck.

The adhesive layer may be a pressure-sensitive adhesive layer. In addition to the organopolysiloxane of Chemical Formula 1 or derivative thereof and the hydrogen siloxane copolymer of Chemical Formula 2 or derivative thereof, an additional component may be included to improve the physical properties of the pressure-sensitive adhesive layer.

The additional component may include silicone gum, MQ resin, or the like. The adhesive layer may adhere to a sensitive portion such as a wafer or an organic coating layer, and has good adhesive strength and maintains a predetermined crosslinking density to maintain the adhesive properties of a product even after a certain period of time.

In addition, the adhesive layer 30 may be slot-die-coated or comma-coated on the conductive layer 20.

In addition, the adhesive layer 20 may be dried with hot air at 60 to 150° C. or 30 to 35 Hz for 90 to 180 seconds. When the drying time or the drying temperature is less than the above range, drying is insufficient, and thus curing or volatilization of the solvent is not completely performed, so that electrical properties such as dielectric constant may be affected.

In the semiconductor adhesive film 1 according to an embodiment of the present disclosure, the adhesive layer 30 may be bonded to the entire semiconductor wafer W within 1.0 sec from a time point at which the center of the semiconductor adhesive film 1 is pressed to bring the semiconductor wafer W into contact with the adhesive layer 30.

It is preferable that the time for which the semiconductor adhesive film 1 is bonded to the entire wafer W is 1 sec or less. The rapid bonding of the semiconductor adhesive film 1 to the wafer W varies according to the wetting performance of the adhesive layer 30 permeating into the surface of the wafer W, and the wetting performance increases as the thickness of the adhesive layer 30 increases. When the wetting performance is weaken and the bonding time exceeds 1 sec, a problem in which the film 1 lifts off on the wafer Was illustrated in FIG. 5 may occur, and the possibility of generating fine bubbles increases. Therefore, in order to form the bonding time of 1 sec or less, the adhesive layer 30 is formed to be 15 μm or more.

In the semiconductor adhesive film 1 according to an embodiment of the present disclosure, the thickness of the base layer 10 may be 25 to 100 μm, 33 to 70 μm, or 38 to 50 μm.

In addition, the thickness of the base layer 10 may be 25 to 100 μm, 33 to 70 μm, or 38 to 50 μm. When the thickness of the base layer 10 is less than the above range, wrinkles may be generated due to shrinkage in a thermal process during coating, resulting in poor appearance. On the contrary, when the thickness exceeds the above range, the dielectric loss is lowered, so that the film may not react with the electrostatic chuck.

The thickness of each of the base layer S, the conductive layer C, and the adhesive layer A may simultaneously satisfy Equation 1 and Equation 2 below.

$$A / ( S + C + A ) \leq 0.5 \qquad [ Equation 1 ]$$

$$C + A \leq S \qquad [ Equation 2 ]$$

When Equations 1 and 2 are satisfied at the same time, it is possible to obtain a semiconductor adhesive film having an excellent burr property.

Hereinafter, Examples of the present disclosure will be described.

### EXAMPLES

### Preparation Example: Base Layer+Conductive Layer+Adhesive Layer

A reaction product was obtained by crosslinking 0.8 wt % of an aqueous solution of a mixture of poly(3,4-ethylenedioxythiophene) polystyrenesulfonate (PEDOT-PSS) and water-dispersed polyurethane (PEDOT-PSS:polyurethane=1:9 wt) with different concentrations (0 wt %, 0.05 wt %, 0.09 wt %, 0.1 wt %, 0.3 wt %, 0.5 wt %, and 0.6 wt %) of aziridine at normal temperature and normal pressure for 45 minutes. Then, the reaction product was gravure-coated on a 25 to 100 μm-thick polyethylene terephthalate base layer, and dried with 35 Hz hot air at 60° C. for 20 sec, 80° C. for 20 sec, and 100° C. for 20 sec to form a 0.03 to 3 μm-thick conductive layer.

27 g of polydimethylsiloxane (weight average molecular weight of about 650,000) of Chemical Formula 1 containing a vinyl group content of 0.2 mmol/g at both ends and 2.7 g of a methylhydrosiloxane-dimethylsiloxene copolymer (weight average molecular weight of about 2,500) of Chemical Formula 2 having an Si—H content of 4 mmol/g were mixed in 70 g of toluene, added with 0.005 g of platinum as a catalyst and then reacted at normal temperature and normal pressure for 200 minutes to obtain a product. Then, the product was slot-die-coated on the conductive layer, and dried with 35 Hz hot air at 60° C. for 50 sec, 110° C. for 50 sec, and 150° C. for 50 sec to form an adhesive layer having a thickness of 15 to 50 μm.

### Test Example 1: Changes in Surface Resistance According to Thickness of Conductive Layer

The surface resistances of Examples 1 to 8 and Comparative Examples 1 and 2 were measured with a surface resistance meter (Mitsubishi Chemical, Japan) when a molar ratio of Si—H/vinyl group was 2.2 and an applied voltage was 1 kV. The results were shown in Table 1.

TABLE 1

| | Com. | | | | | | | Com. |
|---|---|---|---|---|---|---|---|---|
| | Ex. 1 | Ex. 1 | Ex. 2 | Ex. 3 | Ex. 4 | Ex. 5 | Ex. 6 | Ex. 2 |
| Base layer thickness | 50 | 50 | 50 | 50 | 50 | 50 | 50 | 50 |
| (μm) | | | | | | | | |
| Conductive layer | 0.02 | 0.03 | 0.15 | 0.3 | 0.9 | 1.5 | 3 | 3.4 |
| thickness μm | | | | | | | | |
| Adhesive layer | 20 | 20 | 20 | 20 | 20 | 20 | 20 | 20 |
| thickness μm | | | | | | | | |
| Surface Resistance | 1.32 × | 7.54 × | 1.39 × | 9.81 × | 8.84 × | 5.93 × | 3.82 × | 2.83 × |
| (Ω/sq) | 10¹³ | 10¹² | 10¹² | 10¹¹ | 10¹¹ | 10¹¹ | 10¹¹ | 10¹⁰ |

As a result of the test, when the thickness of the conductive layer was 0.03 to 0.3 μm, it was confirmed that the surface resistance value had a target range of 1×10¹¹ to 1×10¹³ Ω/sq.

### Test Example 2: Changes in Surface Resistance and Bonding Time According to Thickness of Adhesive Layer

When the molar ratio of Si—H/vinyl group was 2.2 and the applied voltage was 1 kV, the surface resistances of Examples 7 to 10 and Comparative Examples 3 to 6 were measured with a surface resistance meter (Mitsubishi Chemical, Japan), and the time at which the semiconductor adhesive film 1 was bonded to the entire wafer W was measured. The results were shown in Table 2.

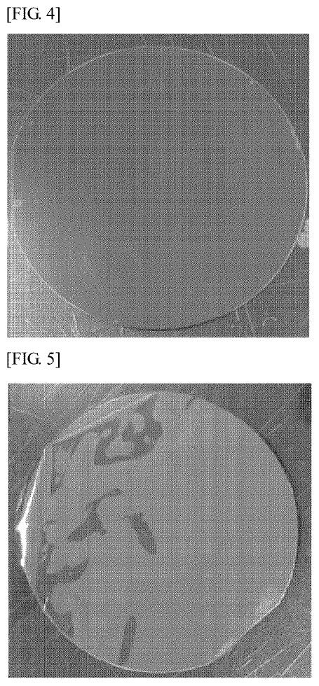

The wafer W was selected as a 200 mm wafer. Referring to FIG. 3, when the film 1 was bonded to the wafer W, a pressure was applied to the center portion, so that the film was in contact with the wafer W. The time for which the semiconductor adhesive film 1 was bonded to the entire wafer W means the time elapsed from when the film 1 was in contact with the wafer W as illustrated in FIG. 3 to when the film 1 was completely bonded to the wafer Was illustrated in FIG. 4. When the film 1 did not completely adhere to the wafer W as illustrated in FIG. 5, it means a state in which the entire film was not bonded.

TABLE 2

| | Com. | Com. | | | | | Com. | Com. |
|---|---|---|---|---|---|---|---|---|
| | Ex. 3 | Ex. 4 | Ex. 7 | Ex. 8 | Ex. 9 | Ex. 10 | Ex. 5 | Ex. 6 |
| Base layer thickness μm | 50 | 50 | 50 | 50 | 50 | 50 | 50 | 50 |
| Conductive layer thickness | 0.15 | 0.15 | 0.15 | 0.15 | 0.15 | 0.15 | 0.15 | 0.15 |
| μm | | | | | | | | |
| Adhesive layer thickness | 5 | 10 | 15 | 20 | 30 | 49.5 | 75 | 100 |
| μm | | | | | | | | |
| Surface resistance (Ω/sq) | 1.0 × | 5.0 × | 2.0 × | 1.39 × | 5.5 × | 9.0 × | 1.2 × | 5.0 × |
| | 10¹⁰ | 10¹⁰ | 10¹¹ | 10¹² | 10¹² | 10¹² | 10¹⁴ | 10¹⁴ |
| Bonding time (sec) | 2 to 3 | 1.5 to 3 | 0.3 to 1 | 0.1 to 0.5 | 0.1 to 0.3 | 0.1 to 0.3 | 0.1 to 0.2 | 0.1 to 0.2 |

When the voltage of 1 kV was applied to the semiconductor adhesive film 1, the surface resistance was 1×10¹¹ to 1×10¹³ Ω/sq. When the surface resistance was less than the above range, the dielectric loss was increased, and thus the wafer W to which the semiconductor adhesive film 1 adhered may not be fixed to the electrostatic chuck. On the contrary, when the surface resistance exceeded the above range, the dielectric loss was decreased, but the fluidity of electrons was reduced, and thus the wafer W to which the semiconductor adhesive film 1 adhered was not fixed to the electrostatic chuck. At this time, in the surface resistance values of the film 1 at the time of applying the voltage of 1 kV depending on the thickness of the adhesive layer 30, in the cases of Comparative Examples 3 and 4, it can be seen that the surface resistance was formed to be less than 1×10¹¹ Ω/sq when the thickness of the adhesive layer 30 was less than 15 μm. In addition, in Comparative Examples 5 and 6, it can be seen that when the thickness of the adhesive layer 30 exceeded 50 μm, the surface resistance exceeded 1×10¹³ Ω/sq. Accordingly, when the voltage of 1 kV was applied to the semiconductor adhesive film 1 when the thickness of the adhesive layer 30 was formed to be 15 to 50 μm, the surface resistance may be formed to be 1×10¹¹ to 1×10¹³ Ω/sq. It was preferred that the time for which the semiconductor adhesive film 1 was bonded to the entire wafer W was formed to be 1 sec or less. The rapid bonding of the semiconductor adhesive film 1 to the wafer W varied according to the wetting performance, and the wetting performance increased as the thickness of the adhesive layer 30 increased. From Table 2, it can be seen that the larger the thickness of the adhesive layer 30, the faster the bonding time. At this time, in Comparative Examples 3 and 4, it can be seen that when the adhesive layer was formed to be less than 15 μm, the bonding time exceeded 1 sec. In addition, when the wetting performance was weakened and the bonding time exceeded 1 sec, a problem in which the film 1 lifted off on the wafer Was illustrated in FIG. 5 may occur, and the possibility of generating fine bubbles increased. Therefore, in order to form the bonding time of 1 sec or less, the adhesive layer 30 was formed to be 15 μm or more.

### Test Example 3: Occurrence of Burr and Bubbles Depending on Thickness of Adhesive Layer

The semiconductor adhesive film 1 was used by cutting a film in the form of a roll, and at this time, when the thickness of the adhesive layer 30 exceeded 50 μm, burr may be generated when the film 1 was cut to contaminate a space between the wafer W and the film 1. In addition, when a ratio of the thickness of the adhesive layer 30 to the total thickness of the semiconductor adhesive film 1 exceeded 50%, the stiffness of the film 1 was weak, so that bubbles were likely to be generated when the film 1 adhered to the wafer W. In addition, as mentioned even in Test Example 2, when the thickness of the adhesive layer 30 was formed to be less than 15 μm, the wetting performance was weakened, and the overall bonding speed between the film 1 and the wafer W was slowed to increase the probability of bubbles to be generated.

A burr test was performed by a pencil hardness test method. In a pencil hardness test device as shown in FIG. 6, the semiconductor adhesive film 1 to be measured was placed on a glass plate. Then, 750 g of a weight was used so that the pressure applied to a pencil having a pencil hardness of 7 H was kept constant. The moving speed of the pencil was formed to 120 mm/s. At this time, whether or not to generate burr in the film 1 was measured.

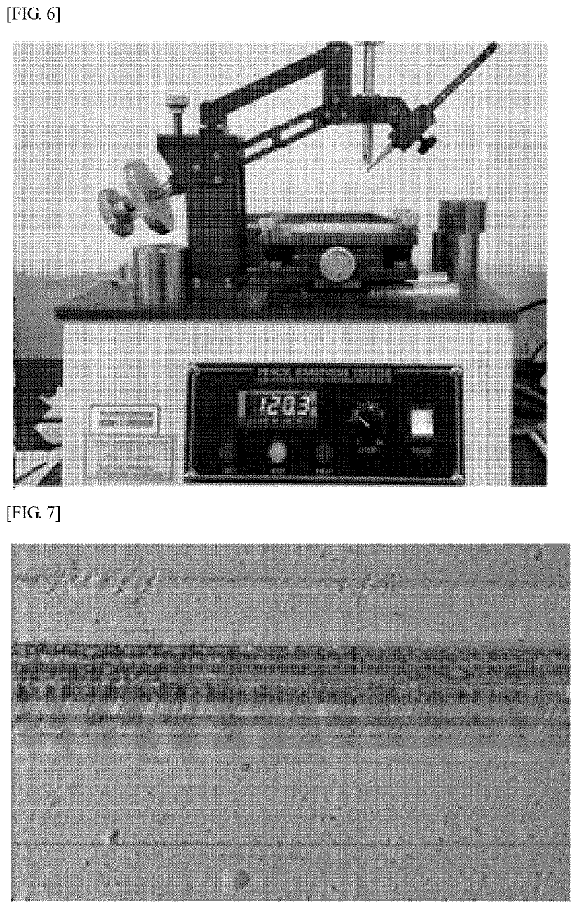

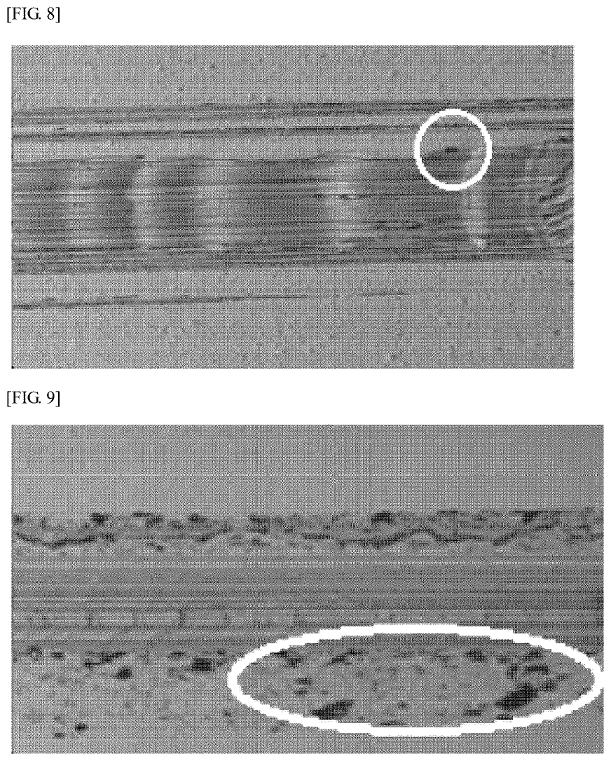

In the Burr test, when the film 1 was observed with an optical microscope, it was evaluated as ‘AA’ when no burr was generated in a portion where a scratch was formed on the film 1 by a pencil as illustrated in FIG. 7, and it was evaluated as ‘A’ when burr was found only in a portion of the film 1 as illustrated in FIG. 8, but the length of the burr was formed to be 20 μm or less. In addition, it was evaluated as ‘B’ when the burr was observed only in a portion of the film 1 as illustrated in FIG. 8, but the length of the burr was formed to be 20 to 40 μm, and it was evaluated as ‘C’ when the burr was generated in the entire film 1 and the length of the burr exceeded 40 μm as illustrated in FIG. 9.

In addition, in evaluation on when the bubbles have been generated, the presence or absence of bubbles between the wafer W and the semiconductor adhesive film 1 was confirmed by pressing through a roll-shaped bar at a temperature of 65° C. using a tape mounting facility (DT-MWM 1230A, Dynatech). At this time, it was evaluated as ‘good’ when the film 1 was well bonded to the entire wafer W without bubbles, and it was evaluated as ‘poor’ when bubbles were present.

TABLE 3

| | Com. | Com. | | | | | Com. | Com. |
|---|---|---|---|---|---|---|---|---|
| | Ex. 7 | Ex. 8 | Ex. 11 | Ex. 12 | Ex. 13 | Ex. 14 | Ex. 9 | Ex. 10 |
| Base layer thickness μm | 25 | 25 | 26 | 100 | 100 | 100 | 25 | 100 |
| Conductive layer | 0.03 | 0.03 | 0.03 | 3 | 3 | 3 | 0.03 | 3 |
| thickness μm | | | | | | | | |
| Adhesive layer thickness | 50 | 35 | 25 | 15 | 17 | 18 | 75 | 10 |
| μm | | | | | | | | |
| Thickness ratio (%) of | 66.64 | 58.30 | 48.99 | 12.71 | 14.167 | 14.876 | 68.72 | 11.21 |
| adhesive layer | | | | | | | | |
| Burr property | B | A | AA | AA | AA | AA | C | AA |
| Bubble property | Poor | Poor | Good | Good | Good | Good | Poor | Poor |

From Table 3, when the thickness of the adhesive layer 30 exceeded 50 μm (Comparative Example 9), it can be seen that the burr property had grade C. When the thickness of the adhesive layer 30 was 50 μm (Comparative Example 7), it can be seen that the burr property had grade B. When the thickness of the adhesive layer 30 was 35 μm (Comparative Example 8), it can be seen that the burr property had grade A. When the thickness of the adhesive layer 30 was 18 to 25 μm (Examples 11 to 14), it can be seen that the burr property had grade AA. In addition, when the thickness ratio of the adhesive layer 30 to the film 1 exceeded 50% (Comparative Examples 7, 8, and 9), it can be seen that bubbles were generated between the film 1 and the wafer W. In the case of Comparative Example 10, it can be seen that the thickness of the adhesive layer was formed to be less than 15 μm, so that the wetting performance was weakened, and voids were generated.

TABLE 4

| | Com. | Com. | | | | | Com. | Com. |
|---|---|---|---|---|---|---|---|---|
| | Ex. 11 | Ex. 12 | Ex. 15 | Ex. 16 | Ex. 17 | Ex. 18 | Ex. 13 | Ex. 14 |
| Base layer thickness | 33 | 33 | 33 | 70 | 70 | 70 | 33 | 70 |
| μm | | | | | | | | |
| Conductive layer | 0.03 | 0.03 | 0.03 | 3 | 3 | 3 | 0.03 | 3 |
| thickness μm | | | | | | | | |
| Adhesive layer | 50 | 35 | 25 | 15 | 17 | 18 | 55 | 13 |
| thickness μm | | | | | | | | |
| Thickness ratio (%) of | 60.22 | 51.45 | 43.08 | 17.045 | 18.8889 | 19.78 | 62.4787 | 15.116 |
| adhesive layer | | | | | | | | |
| Burr property | B | A | AA | AA | AA | AA | C | AA |
| Void property | Poor | Poor | Good | Good | Good | Good | Poor | Poor |

From Table 4, when the thickness of the adhesive layer 30 exceeded 50 μm (Comparative Example 13), it can be seen that the burr property had grade C. When the thickness of the adhesive layer 30 was 50 μm (Comparative Example 11), it can be seen that the burr property had grade B. When the thickness of the adhesive layer 30 was 35 μm (Comparative Example 12), it can be seen that the burr property had grade A. When the thickness of the adhesive layer 30 was 18 to 25 μm (Examples 15 to 18), it can be seen that the burr property had grade AA. From Table 4, when the thickness of the adhesive layer 30 exceeded 50 μm (Comparative Example 13), it can be seen that the burr was generated. In addition, when the thickness ratio of the adhesive layer 30 to the film 1 exceeded 50% (Comparative Examples 11, 12, and 13), it can be seen that bubbles were generated between the film 1 and the wafer W. In the case of Comparative Example 14, it can be seen that the thickness of the adhesive layer was formed to be less than 15 μm, so that the wetting performance was weakened, and voids were generated.

TABLE 5

| | Com. | | | | | | Com. | Com. |
|---|---|---|---|---|---|---|---|---|
| | Ex. 15 | Ex. 19 | Ex. 20 | Ex. 21 | Ex. 22 | Ex. 23 | Ex. 16 | Ex. 17 |
| Base layer thickness | 38 | 38 | 38 | 50 | 50 | 50 | 38 | 50 |
| μm | | | | | | | | |
| Conductive layer | 0.03 | 0.03 | 0.03 | 3 | 3 | 3 | 0.03 | 3 |
| thickness μm | | | | | | | | |
| Adhesive layer | 50 | 35 | 25 | 15 | 17 | 18 | 55 | 13 |
| thickness μm | | | | | | | | |
| Thickness ratio (%) | 56.80 | 47.9255 | 39.66 | 22.0588 | 24.2857 | 25.35 | 59.12 | 19.697 |
| of adhesive layer | | | | | | | | |
| Burr property | B | A | AA | AA | AA | AA | C | AA |
| Bubble property | Poor | Good | Good | Good | Good | Good | Poor | Poor |

From Table 5, when the thickness of the adhesive layer 30 exceeded 50 μm (Comparative Example 16), it can be seen that the burr property had grade C. When the thickness of the adhesive layer 30 was 50 μm (Comparative Example 15), it can be seen that the burr property had grade B. When the thickness of the adhesive layer 30 was 35 μm (Comparative Example 19), it can be seen that the burr property had grade A. When the thickness of the adhesive layer 30 was 18 to 25 μm (Examples 19 to 23), it can be seen that the burr property had grade AA.

From Table 5, when the thickness of the adhesive layer 30 exceeded 50 μm (Comparative Example 16), it can be seen that the burr was generated. In addition, when the thickness ratio of the adhesion layer 30 to the film 1 exceeded 50% (Comparative Examples 15 and 16), it can be seen that bubbles wee generated between the film 1 and the wafer W. In the case of Comparative Example 17, it can be seen that the thickness of the adhesive layer was formed to be less than 15 μm, so that the wetting performance was weakened, and voids were generated.

As shown in Tables 3 to 5 overall, it can be seen that when the thickness of the adhesive layer 30 was formed to be 15 to 50 μm, the occurrence of burr was suppressed, and thus the burr property was kept to grade ‘B’ or higher, and the occurrence of bubbles was suppressed due to the improvement of wetting performance.

In addition, it can be seen that when the thickness of the adhesive layer 30 was formed to be 15 to 35 μm, the occurrence of burr was suppressed, and thus the burr property was kept to grade ‘A’ or higher, and the occurrence of bubbles was suppressed due to the improvement of wetting performance.

In addition, it can be seen that when the thickness of the adhesive layer 30 was formed to be 15 to 25 μm, the occurrence of burr was suppressed, and thus the burr property was kept to grade ‘AA’ or higher, and the occurrence of bubbles was suppressed due to the improvement of wetting performance.

In addition, when the thickness ratio of the adhesive layer 30 to the total thickness of the film 1 was 50% or less, an effect of the stiffness of the base layer 10 on the film 1 was greater than the flexibility of the adhesive layer 30, and thus the stiffness of the film was maintained at a predetermined level or higher, so that voids were not generated when the film 1 and the wafer W were bonded.

### Test Example 4: Occurrence of Burr According to Adhesive Layer Material

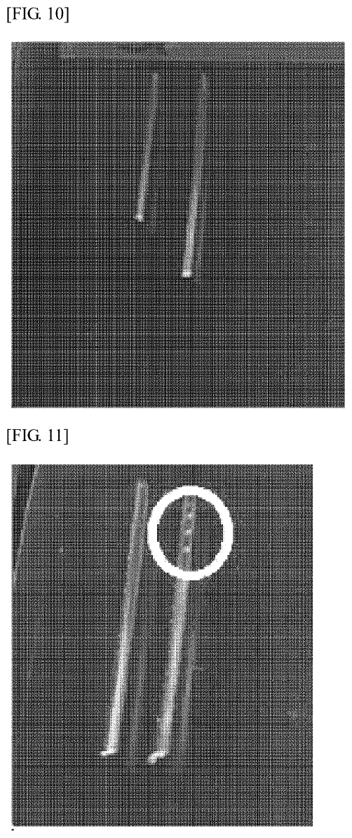

A burr test was performed by a pencil hardness test method. In a pencil hardness test device as shown in FIG. 6, the semiconductor adhesive film 1 to be measured was placed on a glass plate. Then, 750 g of a weight was used so that the pressure applied to a pencil having a pencil hardness of 7 H was kept constant. The moving speed of the pencil was formed to 120 mm/s. At this time, whether or not to generate burr in the film 1 was measured. At this time, the thickness of the base layer 10 of the film 1 was formed to be 50 μm, the thickness of the conductive layer 20 was formed to be 3 μm, and the thickness of the adhesive layer 30 was formed to be 20 μm. In the burr test, when the film 1 was observed with an optical microscope, whether Burr has been generated was confirmed in FIGS. 10 to 12.

TABLE 6

| | Example 24 | Comparative Example 18 | Comparative Example 19 |
|---|---|---|---|
| Adhesive layer | Silicone-based | Acrylic-based (acrylic | Urethane-based |
| material | (adhesive layer | adhesive SYS-7600 from | (urethane adhesive HN-PU125 |
| | of Example 1) | Samyoung Ink Co., Ltd.) | from Hana Chemical Co., Ltd.) |
| Burr occurrence | X | ◯ | ◯ |

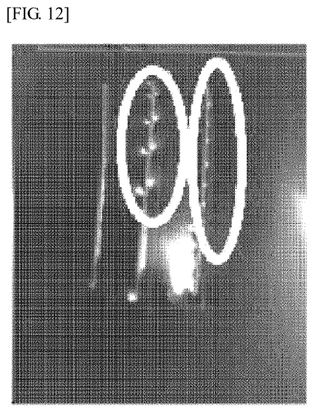

FIG. 10 is a photograph showing that Burr is not generated in the film 1 when an adhesive layer material is formed of a silicone-based material according to Example 24. FIG. 11 is a photograph showing that Burr has been generated in the film 1 when an adhesive layer material is formed of an acrylic-based material according to Comparative Example 18. FIG. 12 is a photograph showing that Burr has been generated in the film 1 when an adhesive layer material is formed of a urethane-based material according to Comparative Example 19. Therefore, it can be seen that the burr property was excellent when the adhesive layer 30 was formed of the silicone-based material.

While the present disclosure has been particularly described with reference to detailed embodiments thereof, the embodiments specifically describe the present disclosure, but the present disclosure is not limited thereto, and it will be apparent that modification and improvement of the present disclosure can be made by those skilled in the art within the technical spirit of the present disclosure.

Simple modifications and changes of the present disclosure all belong to the scope of the present disclosure and a detailed protection scope of the present disclosure will be clear by the appended claims.

1. A semiconductor adhesive film comprising:
a base layer;
a conductive layer formed on the base layer; and
an adhesive layer formed on the conductive layer,
wherein the semiconductor adhesive film has a surface resistance in a range of 1×10¹¹ to 1×10¹³ Ω/sq when a voltage of 1 kV is applied, and
a thickness of the adhesive layer is 15 to 50 μm.

2. The semiconductor adhesive film of claim 1, wherein the thickness of the adhesive layer is 50% or less of a thickness of the semiconductor adhesive film.

3. The semiconductor adhesive film of claim 2, wherein the conductive layer has a thickness of 0.03 to 3 μm.

4. The semiconductor adhesive film of claim 1, further comprising:
a release film formed on the adhesive layer.

5. The semiconductor adhesive film of claim 1, wherein the adhesive layer is bonded to an entire semiconductor wafer within 1.0 sec from a time point at which a center of the semiconductor adhesive film is pressed to bring the semiconductor wafer into contact with the adhesive layer.

6. The semiconductor adhesive film of claim 5, wherein the adhesive layer contains one or more selected from the group consisting of a rubber-based compound, an acrylic-based compound, a silicone-based compound, and a urethane-based compound.

7. The semiconductor adhesive film of claim 6, wherein the thickness of the adhesive layer is 15 to 35 μm or 15 to 25 μm.

8. The semiconductor adhesive film of claim 1, wherein a thickness of the base layer is 25 to 100 μm, 33 to 70 μm, or 38 to 50 μm.

9. The semiconductor adhesive film of claim 1, wherein the thickness of each of the base layer(S), the conductive layer (C) and the adhesive layer (A) simultaneously satisfies the following Equations 1 and 2:
$$A / ( S + C + A ) \leq 0.5 \qquad [ Equation 1 ]$$
$$C + A \leq S . \qquad [ Equation 2 ]$$
